(19) United States
(12) Patent Application Publication
(10) Pub. No.: US 2011/0262740 A1
(43) Pub. Date: Oct. 27, 2011

(54) METAL AND ELECTRONIC DEVICE COATING PROCESS FOR MARINE USE AND OTHER ENVIRONMENTS

(75) Inventors: Sidney Edward Martin, III, Fairhaven, MA (US); Eric Roger Dawicki, Fairhaven, MA (US); Angela Michele Dawicki, Fairhaven, MA (US)

(73) Assignee: Northeast Maritime Institute, Inc., Fairhaven, MA (US)

(21) Appl. No.: 12/988,103

(22) PCT Filed: Mar. 5, 2009
(86) PCT No.: PCT/US09/01410

§ 371 Date: Jan. 18, 2011

Related U.S. Application Data
(62) Division of application No. 12/104,080, filed on Apr. 16, 2008.
Application No. 12/104,080 is a division of application No. 12/104,152, filed on Apr. 16, 2008.
(60) Provisional application No. 61/124,802, filed on Sep. 5, 2007.
(60) Provisional application No. 61/124,797, filed on Oct. 23, 2007.
(60) Provisional application No. 61/124,798, filed on Oct. 23, 2007.
(60) Provisional application No. 61/124,802, filed on Sep. 5, 2007.
(60) Provisional application No. 61/124,797, filed on Oct. 23, 2007.
(60) Provisional application No. 61/124,798, filed on Oct. 23, 2007.

(51) Int. Cl. B32B 3/00; C23C 16/448; C09K 5/00

(52) U.S. Cl. 428/332; 252/71; 252/73; 427/255.28

(57) ABSTRACT

The present disclosure relates, in part, to Parylene based conformal coating compositions having improved properties, e.g., improved heat transfer and durability characteristics, as well as a methods and apparatus to coat objects with these compositions, and objects coated with these compositions. In some aspects, coating compositions comprising Parylene and boron nitride are disclosed. The disclosure also includes objects (e.g., electronic equipment, textiles, etc.) having a conformal coating comprising a Parylene compound and boron nitride.

### RELATED APPLICATIONS

The present invention relates, in part, to U.S. patent application Ser. No. 12/104,080 filed on Apr. 16, 2008 and U.S. patent application Ser. No. 12/104,152 filed on Apr. 16, 2008, the contents of which are incorporated herein by reference in their entirety and the benefit of which is hereby claimed under 35 U.S.C. §120.

### BACKGROUND

Conformal coatings, e.g., those with high electrical resistivity and moisture resistance, are commonly used to protect components in commercial devices employed in the consumer, automotive, military, medical, and aerospace industries, for example. A variety of methods exist for applying such coatings. For example, chemical vapor deposition at low pressure can produce a thin, even conformal (also called conformational) coating on various surfaces. There is a need for improved methods for applying conformal coatings to expand their applications. Moreover, new coating compositions with characteristics that will improve effectiveness in certain applications are also needed. For example, coatings with greater durability and greater heat transfer properties are particularly sought.

### BRIEF SUMMARY OF THE INVENTION

Applicants have discovered, in part, ultra-thin, conformal polymer coatings that resist moisture penetration, and methods and apparatus for applying such coatings to objects. Ultra-thin, conformal polymer coatings that resist moisture penetration can be applied directly to a broad range of objects, including, in particular, “off-the-shelf” electronic equipment. Accordingly, some aspects of the disclosure include compositions, methods and apparatus for coating objects. In other aspects, conformal coating compounds are disclosed, such as Parylene compounds, that are capable of forming an ultra-thin, conformal coating on an object. In other aspects, coating compositions are disclosed that comprise a conformal coating compound capable of forming an ultra-thin, conformal coating and an additive(s), such as a thermally conductive material (e.g., boron nitride), for modifying any one of a number of properties of the conformal coating, including, for example, electrical resistivity, thermal conductivity, light transmittance, hardness, and durability. In other aspects, the disclosure includes “off-the-shelf” electronic equipment, such as cell phones and mp3 players, having ultra-thin, conformal coatings that resist moisture penetration (e.g., waterproof coatings). Methods and apparatus useful for applying an ultra-thin, conformal coating on a surface of an object by vapor deposition are also disclosed. In other aspects, multi-stage heating apparatus for vapor deposition of ultra-thin, conformal polymer coatings are disclosed. The objects to be coated by the coating compositions and methods disclosed herein include electronics equipment, such as cell phones, radios, circuit boards and speakers; equipment used in ocean and space exploration; hazardous waste transportation equipment; medical instruments; paper products; and textiles. Any solid surface of an object can be coated, including plastics, metals, woods, paper and textiles. Biomedical devices (e.g., hearing aids, cochlear ear implant, prosthesis, etc), automotive, electromechanical, artwork (paintings, wood, water colors, chalk, ink, charcoal), military systems components, ammunition, guns, weapons and similar objects may be coated using the methods and coating compositions disclosed herein.

According to some aspects, coating compositions are provided that comprise a conformal coating compound and a thermally conductive material. In some embodiments, the thermally conductive material is dispersed in polymers of the conformal coating compound. In some embodiments, the coating composition is a solid (e.g., a conformal coating) having a hardness of about R80 to about R95. In some embodiments, the coating composition is a gaseous mixture comprising monomers of the conformal coating compound in a gaseous phase. In certain embodiments, the gaseous mixture comprises solid particles of the thermally conductive material.

In some embodiments, the conformal coating compound is a Parylene compound optionally selected from the group consisting of: Parylene D, Parylene C, Parylene N and Parylene HT® compounds. In some embodiments, the coating composition comprises two or more different Parylene compounds. In some embodiments, the coating composition comprises two or more Parylene compounds of different purity levels. In some embodiments, the coating composition has a thermal conductivity that is 5-10% greater than the Parylene compound alone. In some embodiments, the coating composition has a thermal conductivity that exceeds a level which is 10% greater than the Parylene compound alone. In some embodiments, the coating composition has a thermal conductivity that is up to about 5% greater than the Parylene compound alone.

In some embodiments, the thermally conductive material is a ceramic. In some embodiments, the thermally conductive material is selected from the group consisting of: aluminum nitride, aluminum oxide, and boron nitride. In some embodiments, the thermally conductive material has a volume resistivity of greater than 10¹⁰ ohms*cm. In some embodiments, the mass of the thermally conductive material in the coating composition is up to about 3% (or more) of the total mass of the conformal coating compound and the thermally conductive material in the coating composition. In some embodiments, the mass of the thermally conductive material in the coating composition is up to about 1% of the total mass of the conformal coating compound and the thermally conductive material in the coating composition.

In some aspects, a conformal coating is provided that is on at least a portion of a surface of an object. In some embodiments, the conformal coating comprises any of the foregoing coating compositions.

In some embodiments, the conformal coating is on at least a portion of a surface of an object that is an electronic device. The electronic device may optionally be selected from a communication device, a speaker, a cell phone, an audio player, a camera, a video player, a remote control device, a global positioning system, a computer component, a radar display, a depth finder, a fish finder, an emergency position-indicating radio beacon (EPIRB), an emergency locator transmitter (ELT), and a personal locator beacon (PLB).

In some embodiments, the conformal coating is on at least a portion of a surface of an object selected from the group consisting of a paper product; a textile product; an artwork; a circuit board; an ocean exploration device; a space exploration device; a hazardous waste transportation device; an automotive device, a electromechanical device; a military systems component; ammunition; a gun; a weapon; a medical instrument; and a biomedical device, wherein the biomedical device is optionally selected from the group consisting of a hearing aid, a cochlear ear implant, and a prosthesis.

In some embodiments, the conformal coating is on at least a portion of a surface of an object, wherein the surface is a plastic, a metal, a wood, a paper or a textile. In certain embodiments, the surface is an external surface of the object. In certain other embodiments, the surface is an internal surface of the object.

In some aspects, an object is provided that comprises a conformal coating on at least a portion of a surface. In some embodiments, the conformal coating on the surface of the object comprises any of the foregoing coating compositions.

In some embodiments, the object is an electronic device, optionally selected from a communication device, a speaker, a cell phone, an audio player, a camera, a video player, a remote control device, a global positioning system, a computer component, a radar display, a depth finder, a fish finder, an emergency position-indicating radio beacon (EPIRB), an emergency locator transmitter (ELT), and a personal locator beacon (PLB).

In some embodiments, the object is selected from the group consisting of a paper product; a textile product; an artwork; a circuit board; an ocean exploration device; a space exploration device; a hazardous waste transportation device; an automotive device, a electromechanical device; a military systems component; ammunition; a gun; a weapon; a medical instrument; and a biomedical device, wherein the biomedical device is optionally selected from the group consisting of a hearing aid, a cochlear ear implant, and a prosthesis.

In some embodiments, the surface of the object is a plastic, a metal, a wood, a paper or a textile. In certain embodiments, the object is coated on an external surface. In certain other embodiments, the object is coated on an internal surface. In some embodiments, the surface is substantially covered with the conformal coating. A substantially covered surface may be one that is completely covered or sufficiently covered to protect the underlying surface of the object from contact with a substance (e.g., water) against which protection is desired.

In some aspects, methods of applying a conformal coating to an object are provided. In some embodiments, the methods comprise:

A) heating a conformal coating compound to form gaseous monomers of the conformal coating compound,

B) combining a thermally conductive material with the gaseous monomers, thereby forming a gaseous mixture, and

C) contacting an object with the gaseous mixture, under conditions where a conformal coating comprising the conformal coating compound and the thermally conductive material is formed on at least a portion of a surface of the object, thereby applying a conformal coating to the object.

In some embodiments of the methods, the conformal coating compound is a Parylene compound optionally selected from the group consisting of: Parylene D, Parylene C, Parylene N and Parylene HT® compounds.

In some embodiments of the methods, the thermally conductive material is a ceramic. In other embodiments, the thermally conductive material is selected from the group consisting of: aluminum nitride, aluminum oxide, and boron nitride. In certain embodiments, the thermally conductive material is in a solid particle form. In specific embodiments, the solid particles are about 1.8 micron to about 2.5 micron.

In some embodiments, the methods comprise:

A) heating a Parylene compound to a temperature of about 125 to about 200 degrees C. to form a gaseous Parylene compound, wherein the heating of the Parylene compound is performed in two or more heating stages,

B) heating the gaseous Parylene compound to a temperature of about 650 to about 700 degrees C. to cleave the gaseous Parylene compound, thereby forming Parylene monomers,

C) contacting an object with the Parylene monomers, under conditions where a conformal coating, comprising a Parylene polymer, is formed on at least a portion of surface of the object, thereby applying a coating to the object.

In some embodiments of the methods, step A comprises heating the Parylene compound to a temperature of about 125 to about 180 degrees C., and heating the Parylene compound to a temperature of about 200 to about 220 degrees C.

In some embodiments of the methods, heating of the gaseous Parylene compound is performed in two or more stages. In some embodiments, step B comprises heating the gaseous Parylene compound to a temperature of about 680 degrees C., and heating the gaseous Parylene compound to a temperature of at least about 700 degrees C.

In some embodiments, the Parylene compound is selected from a group consisting of Parylene D, Parylene C, Parylene N and Parylene HT® compounds.

In some embodiments, the methods further comprise contacting the object with gaseous silane prior to step C, under conditions wherein the silane activates the surface of the object. In some embodiments, the silane is one or more silanes selected from the group consisting of Silquest® A-174, Silquest® 111 and Silquest® A-174 (NT).

In some embodiments of the foregoing methods, the object is at a temperature of about 5 degrees to about 30 degrees C. during step C. In some embodiments, the conformal coating, which is applied to the surface, is about 100 Angstrom to about 3.0 millimeters. In some embodiments, the conformal coating, which is applied to the surface, is about 0.0025 mm to about 0.050 mm thick.

In some embodiments of the foregoing methods, the object is an electronic device, optionally selected from a communication device, a speaker, a cell phone, an audio player, a camera, a video player, a remote control device, a global positioning system, a computer component, a radar display, a depth finder, a fish finder, an emergency position-indicating radio beacon (EPIRB), an emergency locator transmitter (ELT), and a personal locator beacon (PLB).

In some embodiments of the foregoing methods, the object is selected from the group consisting of a paper product; a textile product; an artwork; a circuit board; an ocean exploration device; a space exploration device; a hazardous waste transportation device; an automotive device, a electromechanical device; a military systems component; ammunition; a gun; a weapon; a medical instrument; and a biomedical device, wherein the biomedical device is optionally selected from the group consisting of a hearing aid, a cochlear ear implant, and a prosthesis.

In some embodiments of the foregoing methods, the surface is a plastic, a metal, a wood, a paper and a textile.

In some aspects, an object is provided having a coating applied to at least a portion of a surface (external or internal) by any of the foregoing methods.

In some aspects, an apparatus for applying a conformal coating to an object is provided. In some embodiments, the apparatus comprises: a vaporization chamber, comprising at least two temperature zones; a pyrolysis chamber that is operably linked to the vaporization chamber; and a vacuum chamber that is operably linked to the pyrolysis chamber. In some embodiments, the apparatus further comprises a connection that operably links the pyrolysis chamber and the vacuum chamber, wherein the connection is capable of transmitting a gas between the pyrolysis chamber and the vacuum chamber and wherein the connection comprises a T-port. In some embodiments, the T-port is operably linked with a means for injecting a thermally conductive material into a gas that is transmitted through the connection from the pyrolysis chamber to the vacuum chamber. In some embodiments, a vacuum produced in the vacuum chamber draws the thermally conductive material through the T-port into the connection comprising the gas.

In some embodiments, the vacuum chamber comprises a deposition chamber operably linked to the pyrolysis chamber and a vacuum generating component. In some embodiments, the vacuum generating component (vacuum means) comprises one or more vacuum pumps.

In some embodiments, the vaporization chamber has two temperature zones. In some embodiments, the vaporization chamber is a tubular furnace.

In some embodiments, the pyrolysis chamber has a plurality of temperature zones. In some embodiments, the pyrolysis chamber has two temperature zones. In some embodiments, the pyrolysis chamber is a tubular furnace.

### BRIEF DESCRIPTION OF DRAWINGS

Further advantages of the present invention may be understood by referring to the following descriptions taken in conjunction with the accompanying drawings, in which:

FIG. 1A-E are diagrams of the chemical structures of varieties of Parylene and Silquest®. FIG. 1A is a diagram of Parylene N. FIG. 1B is a diagram of Parylene C. FIG. 1C is a diagram of Parylene D. FIG. 1D is a diagram of Parylene HT®. FIG. 1E is a diagram of Silquest® A-174 silane (also known as Silquest® A-174 (NT)).

FIG. 2A is a schematic diagram of one embodiment of the apparatus for chemical vapor deposition of Parylene.

FIG. 2B is a schematic diagram of one embodiment of an apparatus to apply a coating of Parylene and powder.

FIG. 3A-C are schematic diagrams of three embodiments of the Parylene-coated objects. FIG. 3A depicts an object coated with separate layers of Parylene and boron nitride, where the boron nitride layer is closest to the object. FIG. 3B depicts an object coated with separate layers of Parylene and boron nitride, where the Parylene layer is closest to the object. FIG. 3C depicts an object coated with a layer of Parylene inter-dispersed with boron nitride.

### DETAILED DESCRIPTION

The disclosure, in some aspects, provides compositions, methods and apparatus for coating objects with conformal polymers. In some aspects, conformal coating compounds (e.g., Parylene) are provided that are capable of forming an ultra-thin, conformal coating on an object. In other aspects, coating compositions are provided that comprise a conformal coating compounds (e.g., Parylene) and an additive (one or more additives), e.g. a thermally conductive material, for modifying any one of a number of properties of the coating, including, for example, electrical resistivity, thermal conductivity, light transmittance, hardness, and durability. In other aspects, objects, such as electronic devices, are provided that have ultra-thin, conformal coatings which resist moisture penetration (e.g., waterproof coatings). Also provided are methods and apparatus useful for applying an ultra-thin, conformal coating on at least a portion of a surface of an object by vapor deposition. In certain aspects, multi-stage heating apparatus are provided which are useful for vapor deposition of ultra-thin, conformal polymer coatings.

A particularly important discovery disclosed herein is that conformal coatings may be applied directly to “pre-assembled” or “off-the-shelf” devices, such as consumer electronics devices. Thus, it is possible with the methods and compositions disclosed herein to apply conformal coatings to all or a portion of the external surfaces of “pre-assembled” or “off-the-shelf” devices (e.g., creating a hermetic or nearly hermetic seal) and thereby protecting internal components of the devices from environment insults, such as moisture penetration and oxidation. Accordingly, using the methods disclosed herein, certain objects, e.g., electronic devices (equipment), do not have to be disassembled, coated and then reassembled, but rather, may be coated in its “off-the-shelf” state. The methods disclosed herein may apply a conformal coating, e.g., comprising a Parylene compound, both to a circuit board inside an electronic device as well as the outside surface of the electronic device (e.g., in one process). Thus, the methods may be used to a particular advantage with “off-the-shelf” electronics equipment. The methods disclosed herein may also be very useful to improve the ease and efficiency by which many other objects are conformally coated.

Objects suitable for conformal coating with the compositions and methods disclosed herein include, but are not limited to, electronics equipment, cameras, circuit boards, computer chips, paper, textiles, batteries, speakers, solid fuel, medical devices, hazardous waste transportation equipment, hazardous waste, medical instruments, equipment used in ocean and space exploration, space suits, and so on. In some embodiments, the object is an electronic device, optionally selected from a communication device, a speaker, a cell phone, an audio player, a camera, a video player, a remote control device, a global positioning system, a computer component, a radar display, a depth finder, a fish finder, an emergency position-indicating radio beacon (EPIRB), an emergency locator transmitter (ELT), and a personal locator beacon (PLB).

In some embodiments, the objects are those which are incompatible with submersion in water, including but not limited to, off-the-shelf electronics components, such as laptop computers, cameras, radios, cell phones, paper, textiles, batteries, speakers, solid fuel, medical devices, paper, space suits and others disclosed herein or known in the art. In other embodiments, the objects may be ones that are degraded upon submersion in water, such as but not limited to, metal screws and other hardware, paper products and textiles. In other embodiments, the objects may be those which require flexibility to be functional, such as audio speakers. In further embodiments, the objects may be those which are desired to be protected from oxygen, such as but not limited to, fuel cells, weapons cartridges and ammunition. In further embodiments, the objects may be those which must be isolated from the environment, such as hazardous waste products. In further embodiments, the objects may be those which require protection from chemical exposure, such as but not limited to, hazardous waste transportation equipment.

The coatings may be applied to objects having a variety of surface materials, include for example ceramics, polymers, plastics, metals, frozen liquids, and so on. In some embodiments, the object to be coated may be one that generates or consumes heat and/or requires a rugged coating. In some embodiments, the object may generate heat or absorb heat, such as cold packs, frozen liquids and gases and heat pumps. In some embodiments, the object may be expected to be subjected to harsh physical impact during its lifetime. In some aspects, methods are provided in the disclosure which may be used to coat such objects and surfaces.

The conformal coatings disclosed herein may be applied to a broad range of devices used in the consumer electronics, commercial marine, recreational boating, military (aerospace and defense), industrial and medical industries, as well as others. In some instances, the conformal coatings are specifically designed to “seal” devices. Such coatings are useful, for example to protect devices commonly used in marine and hazardous environments against operational malfunction caused by exposure to moisture, immersion in water, dust, effects of high wind and chemicals. The coatings may enhance the survivability and sustainability of operational equipment and high value specialty products susceptible to corrosion and degradation.

In some embodiments, the conformal coating may be on the inside and outside surface of the object, and in particular, the conformal coating on the outside of the object may be continuous with the conformal coating on the inside of the object.

In some instances where pretreatment with a compound, e.g., an organic compound, such as silane, is desired, any object that has a solid surface which can be exposed to the pretreatment compound (e.g., in its vapor phase) are suitable. Accordingly, one embodiment provides objects coated with at least one conformal coating compound having been pretreated with a silane, such as Silquest®, where the uncoated objects may be incompatible with immersion in water. Uncoated objects that are incompatible with immersion in water may be those which partially or totally lose functionality after immersion in water. In preferred embodiments, the objects may be those which when uncoated become at least partially non-functional after immersion in water and subsequent drying, including but not limited to, off-the-shelf electronics components, such as laptop computers, radios and cell phones.

Objects coated with at least a conformal coating compound (and optionally pretreated with silane) may have a conformal coating on the outside of the object, as well on the inside of the object if there are gaps in the outer surface of the object that allow the conformal coating compound gases (optionally and/or the silane gases) admission to the inside of the object. In a preferred embodiment, the outside conformal coating is continuous with the inside conformal coating.

The coated objects may be particularly suited for the use in the harsh environmental conditions encountered by the military. In some embodiments, the coated object may meet the applicable requirements of military specifications MIL PRF-38534, the general performance requirements for hybrid microcircuits, Multi-Chip Modules (MCM) and similar devices. In some embodiments, the coated object may meet the applicable requirement of military specifications MIL-PRF-38535, the general performance requirements for integrated circuits or microcircuits. In some embodiments, a coated object may meet the applicable requirements of both military specifications MIL-PRF-38534 and MIL-PRF-38535.

Another embodiment includes objects coated with Parylene and boron nitride compositions (e.g., by methods disclosed herein). The objects to be coated by this method include any object that has a solid surface capable of being of contacted with gaseous Parylene monomers and boron nitride under conditions suitable for forming a conformal coating, which comprises Parylene polymers and boron nitride, on at least a portion of the surface of the object. Such objects include, but are not limited to, electronics equipment, circuit boards, paper, textiles, batteries, speakers, solid fuel, medical devices, hazardous waste transportation equipment, hazardous waste, equipment used in ocean and space exploration, space suits, and others disclosed herein and/or known in the art. In some embodiments, the object may be one which generates heat or consumes heat, such as, but not limited to, computers, drill equipment for deep hole drilling, exposed electronics on oil rigs. In other embodiments, the object may be one that requires a particularly rugged coating.

Objects coated with at least a conformal coating compound and thermally conductive material, e.g., boron nitride, may have a conformal coating on the outside of the object, as well on the inside of the object if there are gaps in the outer surface of the object that allow a gaseous mixture comprising the conformal coating compound and the thermally conductive material (e.g., boron nitride powder particles) admission to the inside of the object. In a preferred embodiment, the outside conformal coating is continuous with the inside conformal coating. For example, an electronics device such as a cell phone may have a conformal coat on the circuit boards and battery within the device as well as on the keyboard and screen of the cell phone.

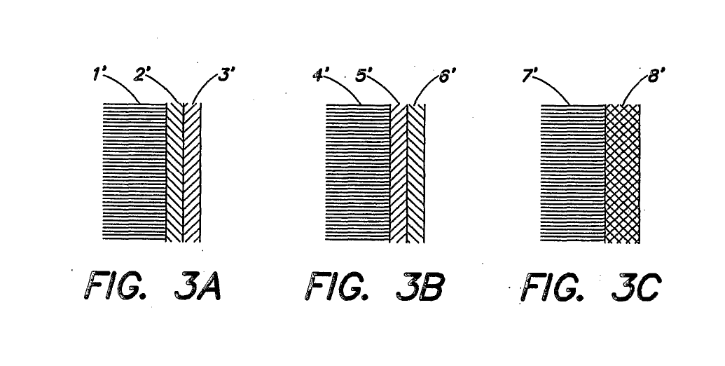

In some embodiments, the Parylene and the boron nitride may be inter-dispersed within the coating 8′ on the object 7′. FIG. 3C. In some embodiments, the inter-dispersion of the Parylene and the boron nitride may be on the molecular level. In some embodiments, the coating of inter-dispersed Parylene and boron nitride may about 0.0025 mm to about 0.050 mm. In other embodiments, the inter-dispersed Parylene and boron nitride coat may be less that about 2.0 mm.

In other embodiments, at least one conformal coating, such as a Parylene conformal coating, and the boron nitride are found in separate layers on the object. Conformal coatings of interest include, but are not limited to, polynaphtahlene (1-4-napthalene), diamine (O-tolidine), polytetrafluoroethylene (Teflon®), polyimides. In preferred embodiments, the polymer coating may be Parylene C. In other embodiments, other forms of Parylene may be used, including but not limited to, Parylene N, Parylene D and Parylene HT®. In preferred embodiments, the layers of boron nitride and polymer coating may be about 0.05 mm thick each. In other preferred embodiments, each layer may contain essentially the polymer coating or essentially boron nitride. In some embodiments, the boron nitrate layer 2′ may be closer to the object 1′ than the Parylene layer 3′. FIG. 3A. In other embodiments, the Parylene layer 5′ may be closer to the object 4′ than the boron nitride 6′. FIG. 3B.

### Conformal Compositions/Coatings

According to some aspects, coating compositions, comprising a conformal coating compound and a thermally conductive material are provided. As used herein, a “conformal coating compound” is a compound (e.g., a partially purified compound, a purified compound, a synthetic compound, an isolated natural compound) that is capable of forming an ultra-thin, pin-hole free, polymeric coating on a surface that conforms to the geometry of that surface. Such coatings are referred to herein as “conformal coatings”. A conformal coating compound may equivalently be referred to as a “conformational coating compound”. Conformal coating compounds may be applied as a coating to the surface of an object by a variety of methods, including for example chemical vapor deposition. For example, vapor phase monomers of conformal coating compounds may be contacted with the surface of an object under conditions where the monomers condense, adsorb to the surface and, concomitantly, polymerize together to form a pin-hole free conformal coating on the surface. The thickness of the coatings may range from about 10 angstroms up to 50 microns or more depending on the application. For example, a coating may have a thickness of up to 3 millimeters. In some embodiments, the coating has a thickness of about 0.0025 mm to about 0.050 mm. The conformal coatings may be electrical insulators (e.g., volume resistivity greater than 10¹⁰ ohms*cm). Alternatively or additionally, the conformal polymers may have a hardness of about R70 to about R90. (Rockwell Hardness Scale). The conformal coatings may also be hydrophobic, depending on the application. Conformal coating compounds may exist in a variety of forms including monomeric and polymeric (e.g., dimeric, multimeric) forms and phase states (e.g., gaseous, solid).

A particularly useful conformal coating compound is a Parylene compound. Parylene is the generic name for members of a unique series of compounds. The basic member of the series, called Parylene N, is poly-para-xylylene, a compound manufactured from di-p-xylylene ([2,2]paracyclophane). Parylene N is a completely linear, highly crystalline material. Parylene C, a second commercially available member of the series, is produced from the same monomer modified only by the substitution of a chlorine atom for one of the aromatic hydrogens. Parylene D, a third member of the series, is produced from the same monomer modified by the substitution of the chlorine atom for two of the aromatic hydrogens. Parylene D is similar in properties to Parylene C with the added ability to withstand higher use temperatures. In some embodiments, the Parylene may be one derived from poly-para-xylylene by the substitution of various chemical moieties. In preferred embodiments, the Parylene may be capable of forming linear, highly crystalline material. Other Parylene molecules, e.g., derivatives and analogs of the foregoing, may also be used. In some embodiments, Parylene compounds provided by a commercial source, e.g., Specialty Coating Systems (SCS), Inc., may be used.

Conformal coating compounds may also include, but are not limited to, polynaphtahlene (1,4-napthalene), diamine (O-tolidine), polytetrafluoroethylene (Teflon®), and polyimides. These polymers may be applied by standard techniques, as will be well known to those of ordinary skill in the art.

Conformal coatings comprising Parylene may be thermally insulating, and do not readily allow the coated object to release heat into the environment. This characteristic of Parylene may be problematic for objects such as electronics equipment that generate heat, which, if not dissipated, can lead to early failure of the equipment. Some Parylene based conformal coatings disclosed herein include thermally conductive materials that facilitate heat dissipation from the coated object. As compared to a Parylene alone coating, such conformal coatings are useful to coat objects that require heat dissipation, either by releasing heat or absorbing heat. The Parylene-based conformal coating compositions disclosed herein also may have increased hardness compared to a coating of Parylene alone. Therefore, the Parylene-based coating compositions may also be useful to coat objects that require a rugged protective coat, such as those that will be subjected to harsh physical impact during their lifetime.

Thus according to some aspects of the disclosure, conformal coating compounds may be combined with other additive(s) to obtain coating compositions having one or more improved performance properties compared with the conformal coating compound alone. For example, coating compositions which have improved heat transfer capabilities may be produced. As used herein, a “thermally conductive material” is a material that is capable of combining with a conformal coating compound to form a coating composition having a thermal conductivity greater than the thermal conductivity of the conformal coating compound alone. The thermally conductive materials disclosed herein typically have higher thermal conductivity compared with conformal coating compounds themselves. Exemplary thermally conductive materials have a thermal conductivity of at least 1, at least 5, at least 10, at least 15, or at least 20 W/(m*K). The skilled artisan will appreciate that there are a variety of methods for measuring thermal conductivity, including for example the testing methods set forth in the following standards: IEEE Standard 98-2002, “Standard for the Preparation of Test Procedures for the Thermal Evaluation of Solid Electrical Insulating Materials”, ISBN 0-7381-3277-2; ASTM Standard D5470-06, “Standard Test Method for Thermal Transmission Properties of Thermally Conductive Electrical Insulation Materials”; ASTM Standard E1225-04, “Standard Test Method for Thermal Conductivity of Solids by Means of the Guarded-Comparative-Longitudinal Heat Flow Technique”; ASTM Standard D5930-01, “Standard Test Method for Thermal Conductivity of Plastics by Means of a Transient Line-Source Technique”; and ISO 22007-2:2008 “Plastics—Determination of thermal conductivity and thermal diffusivity—Part 2: Transient plane heat source (hot disc) method”. Exemplary thermally conductive materials include various ceramic materials, including for example silicon dioxide and silicon nitride. Thermally conductive materials may also be selected from the group consisting of: aluminum nitride, aluminum oxide, and boron nitride. Other thermally conductive materials include for example titania (TiO2). Still others will be apparent to the skilled artisan. In some embodiments, the coating composition comprises a conformal coating compound and lanthanum hexaboride (LaB6). In some embodiments, the coating composition comprises a conformal coating compound and silica (SiO₂).

In some aspects, coating compositions that comprise a Parylene compound, as a conformal coating compound, and a thermally conductive material have greater thermal conductivity than the Parylene compound alone, and in some cases about 10% greater than the thermal conductivity of the Parylene compound alone. In some embodiments, the thermal conductivity of such coating compositions is about 5-10% greater than the Parylene compound alone. Alternatively or additionally, the coating compositions may have a greater hardness than the Parylene alone and particularly greater than about 10% hardness than the Parylene alone.

An exemplary thermally conductive material is boron nitride. Boron nitride (BN) is a binary chemical compound, consisting of equal numbers of boron and nitrogen atoms. Its empirical formula is therefore BN. Boron nitride is isoelectronic with carbon and, like carbon, boron nitrides exists as various polymorphic forms, one of which is analogous to diamond and one analogous to graphite. The diamond-like polymorph is one of the hardest materials known and the graphite-like polymorph is a useful lubricant. In addition, both of these polymorphs exhibit radar-absorptive properties. (Silberberg, Martin S. Chemistry: The Molecular Nature of Matter and Change, Fifth Edition. New York: McGraw-Hill, 2009. p. 483.) Accordingly, in some aspects, the disclosure provides coating compositions which may contain a Parylene compound and boron nitride. In these compositions, the Parylene compound and boron nitride may be inter-dispersed (e.g., boron nitride particles may be dispersed among Parylene polymers). While any Parylene compound may be used in these compositions, Parylene D, Parylene C, Parylene N and Parylene HT® compounds may be preferred, and Parylene C compound may be particularly preferred. In these compositions, the boron nitride may have a hexagonal plate structure. In some embodiments, the weight of boron nitride to the total weight of Parylene compound and boron nitride may be less then about 80%. In some embodiments, the weight of boron nitride may be up to about 1%, up to about 2%, up to about 3%, up to about 5%, up to about 10%, or up to about 20% of the total weight of the Parylene compound and boron nitride.

In some embodiments, a coating composition may consist essentially of Parylene and boron nitride. In other embodiments, a coating composition consists of Parylene and boron nitride. In some embodiments, the Parylene and boron nitride comprise at least about 50%, at least about 70%, at least about 90%, at least about 95%, at least about 99%, or at least about 99.9% of the composition.

In some embodiments coatings on an object comprising Parylene and boron nitride, the boron nitride may be inter-dispersed in Parylene in the coating (dispersed in a polymer of Parylene compounds). While any Parylene may be used in these objects, Parylene C, Parylene N, Parylene D and Parylene HT® may be preferred, and Parylene C particularly preferred. In some embodiments, the coating may be about 0.0025 mm to about 0.050 mm thick.

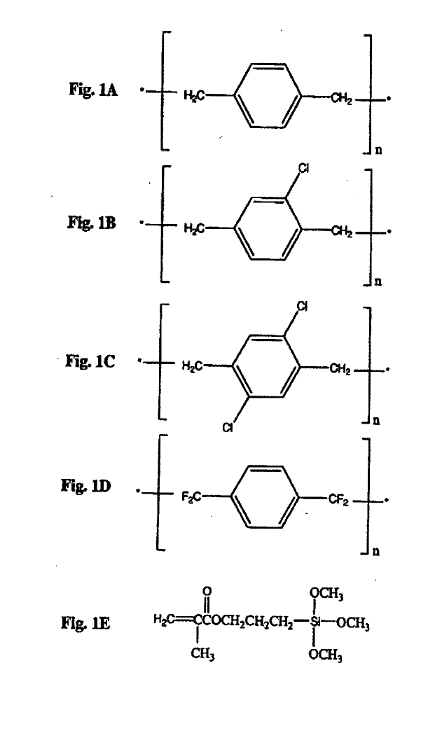

While in some embodiments, this Parylene-boron nitride coating composition may contain Parylene C, in other embodiments, it may contain Parylene D, Parylene N or Parylene HT®. FIGS. 1A, 1B, 1C and 1D. In some embodiments, the Parylene may be derived from Parylene N, or poly-para-xylylene, by the substitution of various chemical moieties. In preferred embodiments, the Parylene forms a completely linear, highly crystalline material. In some embodiments, the boron nitride may have a hexagonal plate structure. In some embodiments, the Parylene and boron nitride form separate layers within the Parylene composition. In some embodiments, the Parylene composition may have strong covalent bonds within the Parylene and boron nitride layers. In other embodiments, the Parylene composition may have weak Van der Waals forces between the Parylene and boron nitride layers.

In some embodiments, a Parylene composition may have greater thermal conductivity than Parylene alone, e.g., as measured in (cal/sec)/cm²/C. In specific embodiments, a Parylene-boron nitride composition may have greater than about 10%, greater than about 30%, or greater than about 50% thermal conductivity than the Parylene alone. In other embodiments, a Parylene composition may have greater hardness than Parylene alone as defined by Rockwell hardness test. E. L. Tobolski & A. Fee, Macroindentation Hardness Testing ASM Handbook. Volume 8: Mechanical Testing and Evaluation, 203-211 (ASM International, 2000). In specific embodiments, the Parylene-boron nitride composition may have greater than about 10%, greater than about 30%, greater than about 50% or greater than about 90% hardness than the Parylene alone. The relative amounts of Parylene and boron nitride in the Parylene-boron nitride composition may determine the thermal conductivity and hardness of the composition. In some embodiments, the weight of boron nitride in the total weight of Parylene and boron nitride in the composition will be less than about 5%, less than about 10%, less than about 20%, less than about 40%, less than about 60%, or less than about 80%. In some embodiments, the weight of boron nitride in the total weight of Parylene and boron nitride in the composition will be up to about 1%, up to about 2%, up to about 3%, or up to about 4%.

In some cases, objects may require prior treatment to make the surfaces of the object more amenable to the adherence of a conformal coating, such as by applying a silane. Pre-treatment methods may entail immersing the object in a solution comprising a suitable compound, including for example an organic compound, such as silane, then removing the object from the silane-solution and allowing the object to dry. Such pretreatments can improve surface bonding of conformal coating compounds and upgrade (improve) mechanical and electrical properties.

In cases where an object may be destroyed by submersion in a solution, e.g., electronics devices, an alternative pretreatment method may be used which includes coating the object with silane. For example, silane may be applied in a vapor phase to an object to be coated with a conformal coating comprising a Parylene compound. This may allow some objects, e.g., those that are incompatible with immersion but that require surface pretreatment with silane, to be coated with Parylene.

In another aspect, the disclosure includes objects with at least one coat of a conformal coating compound and at least one coat of boron nitride. In some embodiments, the conformal coating compound may be polynaphtahlene, diamine, polytetratluoroethylene, polyimides. Parylene C, Parylene N, Parylene D or Parylene HT®, and may be preferably Parylene C. In some embodiments, the boron nitride coat may be closer to the object than the polymer coat, while in other embodiments, the polymer coat may be closer to the object than the boron nitride coat. In some embodiments, the coatings of boron nitride and polymer may be at least about 0.05 mm thick each.

### Conformal Coating Apparatus

Apparatus useful for applying an ultra-thin, conformal coating on a surface of an object by vapor deposition are also disclosed. In other aspects, multi-stage heating apparatus for vapor deposition of ultra-thin, conformal polymer coatings are disclosed.

In some aspects, the disclosure provides an apparatus to apply a conformal coating comprising Parylene, which includes a vaporization chamber with a plurality of (two or more) temperature zones that is operably linked to a pyrolysis chamber that is operably linked to a vacuum chamber. In some embodiments, the vacuum chamber may include a deposition chamber that is operably linked to the pyrolysis chamber and a vacuum means, and the vacuum means may be one or more vacuum pumps. In some embodiments, the vaporization chamber may have a plurality of temperature zones, preferably two temperature zones. In other embodiments, the pyrolysis chamber may have a plurality of temperature zones, preferably two temperature zones. In some embodiments, the vaporization chamber and/or the pyrolysis chamber may be a tubular furnace.

Other apparatus for chemical vapor deposition of conformal coating compounds onto objects are known in the art. See for example, U.S. Pat. Nos. 4,945,856, 5,078,091, 5,268,033, 5,488,833, 5,534,068, 5,536,319, 5,536,321, 5,536,322, 5,538,758, 5,556,473, 5,641,358, 5,709,753, 6,406,544, 6,737,224, and 6,406,544, all of which are incorporated by reference herein.

In another aspect, the disclosure provides an apparatus to apply a conformal coating comprising a conformal coating compound and a thermally conductive material, which may include a vaporization chamber that is operably linked to a pyrolysis chamber that is operably linked to a vacuum chamber, wherein a connection comprising a T-port operably links the pyrolysis chamber to the vacuum chamber. In some embodiments, the connection operably linking the pyrolysis chamber and the vacuum chamber may be a means for transmitting gas from the pyrolysis chamber to the vacuum chamber. In other embodiments, the T-port may be operably connected to a means for injecting solid particles (e.g., a powder) or another gas into the gas transmitted through the connection. In some embodiments, the vacuum chamber may contain a deposition chamber operably linked to the pyrolysis chamber and a vacuum means, where the vacuum means may be one or more vacuum pumps.

One embodiment is an apparatus for the chemical vapor deposition of Parylene which may comprise an improved vaporization chamber and/or pyrolysis chamber. While this apparatus may be particularly useful for the chemical vapor deposition of Parylene, is may also be used to vapor deposit other conformal coating compound, including but not limited to, polynaphtahlene (1,4-napthalene), diamine (O-tolidine), polytetrafluoroethylene (Teflon®), polyimides, and others that will be well-known to those in the art. In some embodiments, the apparatus comprises a vaporization chamber and/or a pyrolysis chamber with a plurality of temperature zones. While not limiting the operation of the apparatus, it is thought that by allowing different temperature set points within each chamber, the rate of heating of Parylene is improved. The multi-zoned vaporization and pyrolysis chambers may allow the Parylene to be uniformly cleaved into a monomer, and allow better control of the final thickness of the Parylene coat on the object. The Parylene may remain a monomer longer in the deposition chamber so that it can be better spread throughout the deposition chamber.

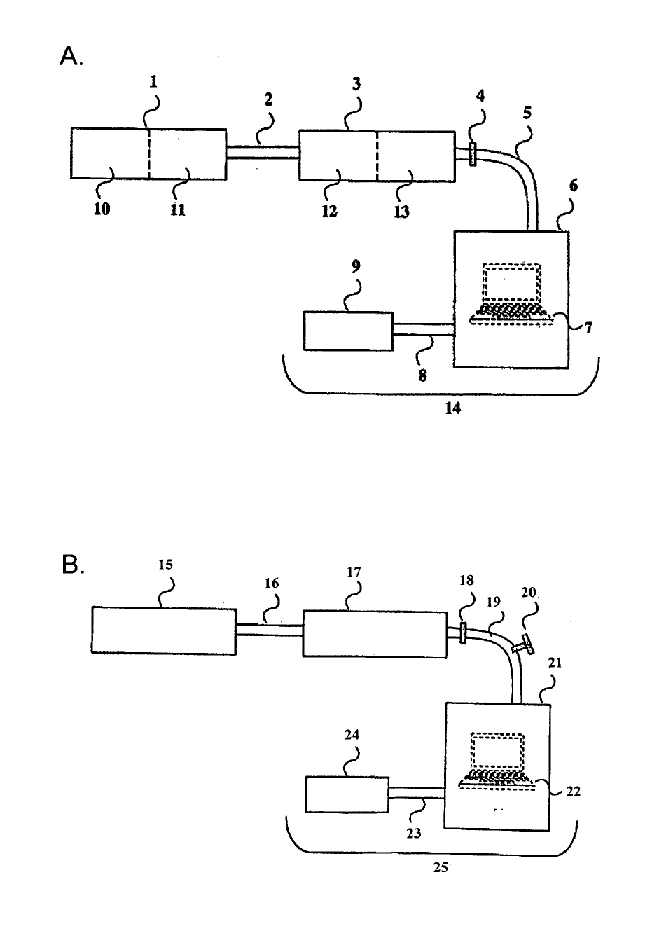

FIG. 2A shows a Parylene coating apparatus. The vaporization chamber 1 may have two temperature zones 10 and 11. The pyrolysis chamber 3 also may have two temperature zones 12 and 13. The vaporization chamber 1 may be operably linked to the pyrolysis chamber 3 by a component 2 that may be capable of communicating gas from the vaporization chamber 1 to the pyrolysis chamber 3. The pyrolysis chamber 3 may be operably linked to the vacuum chamber 14, which may comprise a deposition chamber 6 and may be operably linked to a vacuum means 9 by a component 8 which may be capable of pulling a vacuum on the deposition chamber 6. The component 5 operably linking the pyrolysis chamber 3 to the vacuum chamber 14 may be capable of communicating gas from the pyrolysis chamber 3 to the vacuum chamber 14, and also may include a valve 4 that is capable of regulating the flow of gas from the pyrolysis chamber 3 to the vacuum system 14.

The vaporization chamber 1 may be any furnace/heating system that is capable of heating a solid to about 150 to about 200 degrees C. In preferred embodiments, the vaporization chamber is capable of heating a gas to 1200 degrees C. In some embodiments, the vaporization chamber 1 may be capable of containing gases. The vaporization chamber 1 may also be capable of generating zones within its heating chamber that are different temperatures. Finally, the vaporization chamber 1 may be capable of maintaining a high vacuum. In preferred embodiments, the vaporization chamber may support a vacuum of at least about 0.1 Torr.

The vaporization chamber 1 may be operably linked to the pyrolysis chamber 3 by many components that will be well known to those of ordinary skill in the art. The operable connection between the vaporization chamber 1 and pyrolysis chamber 3 may be, in some embodiments, a connection that allows gas to pass from the vaporization chamber 1 to the pyrolysis chamber. In some embodiments, this component 2 may be a glass tube, a retort, or a metal tube, among others. In other embodiments, this component 2 may also contain valves, temperature sensors, other sensors, and other conventional components, as will be well know to those in the art.

The pyrolysis chamber 3 may be any furnace/heating system that is capable of heating a gas to about 650 to about 700 degrees C. In some embodiments, the pyrolysis chamber 3 may be capable of containing gases. In some embodiments, the pyrolysis chamber 3 may be capable of generating zones within its heating chamber that are different temperatures. Finally, in some embodiments, the pyrolysis chamber 3 may be capable of maintain a high vacuum. In preferred embodiments, the vaporization chamber may support a vacuum of at least about 0.1 Torr.

The vaporization chamber and the pyrolysis chamber, preferably, may be furnaces capable of generating two or more temperature zones within their chamber. In a preferred embodiment, the furnace has two temperature zones. In some embodiments, the temperature zones are situated in the furnace chamber such that a gas will move sequentially through the temperature zones before exiting the furnace. Preferably, the furnace may have a maximum temperature of 1200 degrees C. In a preferred embodiment, the furnace is a tubular furnace. In other embodiments, the furnace may have a glass retort. The specific parameters of one embodiment of a two zoned furnace suitable to be used as the vaporization chamber and/or the pyrolysis chamber may be found in Example 2.

The pyrolysis chamber 3 may be operably linked to the vacuum system 14 by many components that will be well known to those of ordinary skill in the art. The operable connection between the pyrolysis chamber and the vacuum system 14 may be, in some embodiments, a connection that allows gas to pass from the pyrolysis chamber to the vacuum system 14. In some embodiments, this component may be a glass tube, a retort, or a metal tube, among others. In other embodiments, this component may contain valves, temperature sensors, other sensors, and other conventional components, as will be well know to those in the art. In a preferred embodiment, component may contain one or more valves by which the flow of gas through the component may be regulated.

The vacuum system may contain a deposition chamber 6 which may be operably connected 8 to a vacuum means 9. In some embodiments, the operable connector 8 may be capable of holding a vacuum up to at least about 0.05 Torr, and preferably at least about 1×10⁴ Torr. In other embodiments, the vacuum means 9 may be one or more vacuum pumps, which may be capable of pulling a vacuum on the deposition chamber of at least about 0.05 Torr, and preferably at least about 1×10⁴ Torr. In some embodiments, the deposition chamber may be of sufficient size to contain the object to be coated 7. In other embodiments, the deposition chamber may be capable of holding a vacuum of at least about 0.05 Torr, and preferably at least about 1×10⁴ Torr range.

Another embodiment disclosed herein is an apparatus useful for the chemical vapor deposition of the Parylene and boron nitride composition which contains a means to inject a powder into the chemical vapor prior to deposition. FIG. 2B shows a coating apparatus according to one embodiment. The vaporization chamber may be operably linked to the pyrolysis chamber by a component that may be capable of communicating gas from the vaporization chamber to the pyrolysis chamber 17. The pyrolysis chamber may be operably linked to the vacuum chamber 25, which may comprise a deposition chamber 21 and may be operably linked to a vacuum means 24 by a component 23 which may be capable of pulling a vacuum on the deposition chamber 21. The component 19 operably linking the pyrolysis chamber to the vacuum chamber 25 may be capable of communicating gas from the pyrolysis chamber to the vacuum chamber 25, and also may include a valve 18 that is capable of regulating the flow of gas from the pyrolysis chamber to the vacuum system 25. Component 19 may also have a T-port 20, also called a “tee nipple.” In some embodiments, the T-port may be operably connected to a means for injecting a powder into the gas transmitted through component 19. In some embodiments, the means for injecting a power includes, but is not limited to, ovens, power coat equipment and compressed air. In a preferred embodiment, the means for injecting a power includes a power container operably linked to an electronic valve, which is operably linked to the T-port.

The vaporization chamber may be any furnace/heating system that is capable of heating a solid to about 150 to about 200 degrees C. In some embodiments, the vaporization chamber may be capable of containing gases. Finally, the vaporization chamber may be capable of maintaining a high vacuum.

The vaporization chamber may be operably linked to the pyrolysis chamber by many components that will be well known to those of ordinary skill in the art. The operable connection between the vaporization chamber and pyrolysis chamber may be, in some embodiments, a connection that allows gas to pass from the vaporization chamber to the pyrolysis chamber. In some embodiments, this component may be a glass tube, a retort, or a metal tube, among others. In other embodiments, this component may also contain valves, temperature sensors, other sensors, and other conventional components, as will be well know to those in the art.

The pyrolysis chamber may be any furnace/heating system that is capable of heating a gas to about 650 to about 700 degrees C. In some embodiments, the pyrolysis chamber may be capable of containing gases. Finally, in some embodiments, the pyrolysis chamber may be capable of maintaining a high vacuum, preferably at least 0.1 Torr.

The pyrolysis chamber may be operably linked to the vacuum system 25 by many components that will be well known to those of ordinary skill in the art. The operable connection between the pyrolysis chamber and the vacuum system 25 may be, in some embodiments, a connection that allows gas to pass from the pyrolysis chamber to the vacuum system 25. In some embodiments, this component 19 may be a glass tube, a retort, or a metal tube, among others. In other embodiments, this component 19 may contain valves, temperature sensors, other sensors, and other conventional components, as will be well know to those in the art. In a preferred embodiment, component 19 may contain one or more valves by which the flow of gas through the component 19 may be regulated.

The vacuum system 25 may contain a deposition chamber 21 which may be operably connected by component 23 to a vacuum means 24. In some embodiments, the connector 8 may be capable of holding a vacuum up to at least about 0.05 Torr. In other embodiments, the vacuum means 24 may be one or more vacuum pumps, which may be capable of pulling a vacuum on the deposition chamber of at least about 0.05 Torr. In some embodiments, the deposition chamber may be of sufficient size to contain the object to be coated 22. In other embodiments, the deposition chamber may be capable of holding a vacuum of at least about 0.05 Torr.

### Conformal Coating Methods

Methods for applying an ultra-thin, conformal coating on a surface of an object by vapor deposition are also disclosed. In some aspects, multi-stage heating methods for vapor deposition of ultra-thin, conformal coatings are disclosed. In other aspects, methods for vapor deposition of ultra-thin, conformal coatings comprising additives, such as thermally conductive materials, are disclosed.

The conformal coating deposition process disclosed herein may preferably be carried out in a closed system under negative pressure. For example, Parylene compounds are deposited from a vapor phase at a low pressure, e.g., of around 0.1 Torr, to form conformal coatings. In this example, a first step is vaporization of solid Parylene dimers at approximately 150 degrees C. in a vaporization chamber. A second step is a quantitative cleavage (pyrolysis) of the dimer at the two methylene-methylene bonds, e.g., at about 680 degrees C., in a pyrolysis chamber to yield the stable monomer diradical, para-xylylene. Finally, the monomer in gas form enters a room temperature deposition chamber where it adsorbs and polymerizes on the object to be coated. The closed system preferably has separate chambers for the vaporization, pyrolysis and deposition of the Parylene, with the chambers being connected with the appropriate plumbing or tubular connections.

The conformal coating compound may be provided for use in the methods in a variety of forms and purities levels. In some embodiments, the conformal coating compound is provided at a purity level of about 90%, about 92.5%, about 95%, about 96%, about 97%, about 98%, about 98.5%, about 99%, about 99.5%, about 99.9%, or up to about 100% purity. In some embodiments, the conformal coating compound is provided as a blend of conformal coating compounds (e.g., of the same type, e.g., Parylene C) from different sources and/or of different purity levels. In some embodiments, the conformal coating compound is provided as a blend of conformal coating compounds of multiple types (e.g., Parylene C, Parylene N, Parylene D, Parylene HT®.).

According to other aspects, methods of applying a conformal coating to an object involve heating a Parylene compound to a temperature of about 125 to about 200 degrees C. to form a gaseous Parylene compound, wherein the heating of the Parylene compound is performed in two or more heating stages, heating the gaseous Parylene compound to a temperature of about 650 to about 700 degrees C. to cleave the gaseous Parylene compound, thereby forming Parylene monomers, and contacting an object with the Parylene monomers, under conditions where a conformal coating, comprising a Parylene polymer, is formed on at least a portion of surface of the object, thereby applying a coating to the object. In some embodiments, the Parylene compound is heated to a temperature of about 125 to about 180 degrees C., and then heated to a temperature of about 200 to about 220 degrees C. In some embodiments, the gaseous Parylene compound is heated in two or more stages. For example, the gaseous Parylene compound may be heated to a temperature of about 680 degrees C., and then to a temperature of at least about 700 degrees C.

In some cases, the methods may be useful for applying a uniform, thin layer of a conformal coating comprising Parylene within a vacuum chamber at 25 degrees C. using standard chemical vapor deposition practices, and may be applied in thicknesses ranging, e.g., from 0.01 to 3.0 millimeters, depending on the item coated. The item once coated may be weatherproof and water resistant, and may withstand exposure to extreme weather conditions and exposure to most chemicals. Any solid surface may be coated, including plastics, metals, woods, paper and textiles. Sample applications are disclosed herein include, but are not limited to: electronics equipment, such as cell phones, radios; circuit boards and speakers; equipment used in ocean and space exploration, or oil rig operations; hazardous waste transportation equipment; medical instruments; paper products; and textiles.

In some embodiments, the length of time that the object may be contacted with the gaseous Parylene monomers may be varied to control the final thickness of the Parylene coat on the object. In various embodiments, the final thickness of the Parylene coating may be between about 100 Angstrom to about 3.0 millimeters. In some embodiments, the final thickness of the Parylene coating may be between about 0.5 millimeters to about 3.0 millimeters. In some embodiments, the final thickness of the Parylene coating may be between about 0.0025 millimeters to about 0.050 millimeters. Preferably, a deposition time from about 2 hours to about 18 hours (e.g., hours) may be used to achieve a Parylene coat thickness of about 0.002 inches (0.050 mm), depending on the temperature of the deposition chamber. The choice of final thickness of Parylene coating may depend to some degree on the object to be coated and the final use of the object. Thinner final coats may be desirable for objects that require some movement to be functional, such as power buttons. Thicker coatings may be desirable for objects that will be submerged in water.

The adhesion of certain coating compositions, e.g., those comprising Parylene compounds, to a wide variety of objects can be improved by pre-treating the surface of the object to be coated with an organic compound, such as silane, prior to applying the conformal coating. Silane treatment forms radicals on the surface of the object to which Parylene can bond. Two silanes, vinyl trichlorosilane in either xylene, isopropanyl alcohol, or Freon, and gamma-methacryloxypropyltrimethoxy silane (Silquest® A-174 silane or Silquest® A-174 (NT) silane) in a methanol-water solvent have been used for this purpose. However, electronics components cannot tolerate electrical paths that are developed either by direct contact with a liquid that allows conduction of electricity, nor are they compatible with the ion residue often left after the evaporation of water or the liquid in which it was immersed. Even if there is no immediate growth, dendritic conductors may grow later on, due to the voltage between conductors on the electronics component. These short circuits caused by the conductive fluids and dendrites can drain batteries and allow high currents to flow in areas in which they were not intended, and result in unintended circuit operation or failure. Often, it is best if sometimes the components of electronic equipment, such as circuit boards, must be silane and Parylene coated separately, and then assembled into a finished product.

In some aspects, the disclosure provides methods to coat objects with silanes such as Silquest® saline. In some embodiments, the methods may involve: (A.) vaporizing silane by heating it to its evaporation point to form gaseous silane; and (B.) contacting at least a portion of a surface of an object to be coated (e.g., a surface intended to be coated with a conformal coating, e.g., comprising Parylene) with the gaseous silane of Step A. In some embodiments, the silane may be Silquest® A-174, Silquest® 111 or Silquest® A-174 (NT), and may be preferably Silquest® A-174. In some embodiments, in Step A, the silane may be vaporized in a 50:50 solution with water. In some embodiments, in Step A, the silane may be vaporized at 80 degrees C. for about 2 hours

In some aspects, the disclosure provides methods for applying a pretreatment with silane and a Parylene coating compound to at least a portion of a surface of an object. The methods may include: (A.) vaporizing Parylene dimer by heating it to 150-200 degrees C. to form gaseous Parylene dimers; (B.) cleaving gaseous Parylene dimers to gaseous Parylene monomers by heating gaseous Parylene dimers to 650 to 700 degrees C.; (C.) vaporizing silane by heating it to its evaporation point to form gaseous silane; (D.) contacting the object to be coated with Parylene with the gaseous silane of Step C; and (E.) contacting the object to be coated with Parylene with the gaseous Parylene monomers of Step B for sufficient time to deposit coat of Parylene of a final thickness. In some embodiments, the Parylene may be selected from a group consisting of Parylene D, Parylene C, Parylene N, Parylene HT, and a Parylene derived from Parylene N, and may preferably be Parylene C. In some embodiments, the silane may be Silquest®, Silquest® A-174, Silquest® 111 or Silquest® A-174 (NT), and may preferably be Silquest® A-174.

In some embodiments, in Step A, the Parylene dimer may be vaporized by heating in two or more stages, and preferably in two stages of about 170 degrees C., and about 200 degrees C. to about 220 degrees C. In some embodiments, in Step B, the Parylene dimer may be cleaved by heating in two or more stages, and preferably in two stages of about 680 degrees C. and to more than about 700 degrees C. In some embodiments, in Step C, the silane may be vaporized in a 50:50 solution with water. In other embodiments, in Step C the silane may be vaporized at 80 degrees C. for about 2 hours. In some embodiments, the final thickness of the Parylene coat may be from about 100 Angstrom to about 3.0 mm.

Methods that comprise pre-treating the objects with a silane compound may include the following steps:

A. vaporizing a Parylene dimer form by heating to 150-200 degrees C. to form gaseous Parylene dieters;

B. cleaving gaseous Parylene dimers to gaseous Parylene monomers by heating gaseous Parylene dimers to about 650 to about 700 degrees C.;

C. vaporizing silane by heating it to its evaporation point to form gaseous silane;

D. contacting an object to be coated with gaseous silane; and

E. contacting the object to be coated with gaseous Parylene monomers for sufficient time to deposit a coat of Parylene of a final thickness. Steps A, B and E may be performed by any manner that is currently in use for the coating of objects with Parylene, as will be well-known to those of ordinary skill in the art. Further, any of the steps may be performed in an order different that than the one presented. For example, Step D may be performed prior to Step A. Further, some steps may be performed simultaneously with other steps: for example, Step D may be performed simultaneously with Step A. In preferred embodiments, Parylene C may be used. See FIG. 1B. In other embodiments, other forms of Parylene may be used, including but not limited to, Parylene N, Parylene D and Parylene HT®. See FIGS. 1A, 1B and 1D. In some embodiments, the Parylene may be derived from Parylene N, or poly-para-xylylene, by the substitution of various chemical moieties. In preferred embodiments, the Parylene may form completely linear, highly crystalline material. In the Examples section, an embodiment of the method is set forth with a more detailed description on how the method may be performed.

In some embodiments, Step A, vaporizing Parylene dimer form by heating to 150-200 degrees C. to form gaseous Parylene dimers, may be performed in a furnace chamber. In preferred embodiments, the Parylene dimer is heated in stages to the desired 150-200 degrees C. In some embodiments, this staged heating of the Parylene dimer takes place in a furnace chamber that is multi-zoned, allowing for different temperature set points in different zones of the furnace chamber. While not limiting the method of action of this staged heating procedure, it is thought that the method allows the Parylene to be uniformly “cracked” as a monomer and allow better control of the thickness of the final Parylene coating on the object, as it will remain a monomer longer in the deposition chamber so that it can spread throughout the deposition chamber. In some embodiments, the Parylene dimer may be vaporized by heating in 2 stages, 3 stages, 4 stages, or more than 4 stages. In some embodiments, the temperatures of the stages are about 170 degrees C., and about 200 to about 220 degrees C. While not limited the a particular theory, the inventors believe in the first stage of vaporization, the Parylene will be vaporized, and in the second stage the vapor will be preheated to that when it enters the Pyrolization chamber, it will be cleaved into a monomer at a higher rare.

In some embodiments, Step B, cleaving gaseous Parylene dimers to gaseous Parylene monomers by heating gaseous Parylene dimers to 650 to 700 degrees C., may be performed in a furnace chamber. In preferred embodiments, the gaseous Parylene dimer is heated in stages to the desired 650 to 700 degrees C. In some embodiments, this staged heating of the gaseous Parylene dimer takes place in a furnace chamber that is multi-zoned, allowing for different temperature set points in different zones of the furnace chamber. In some embodiments, the Parylene dimer is cleaved to monomers by heating in 2 stages, 3 stages, 4 stages, or more than 4 stages. In some embodiments, the temperatures of the stages are about 680 degrees C. and more than about 700 degrees C. While not limited to a particular theory, it is thought that in the first stage of heating, the gaseous Parylene dimers will be cleaved into a monomers, and in the second state of heating, the gaseous monomers will be heated further to above about 700 degrees C. to assure that the gaseous monomers are in the deposition chamber longer so as to fill it more evenly.

The methods may utilize a step in which gaseous silane (FIG. 1E) may be brought into contact with the object to be coated (Step D). This step is particularly advantageous to aid the Parylene coating hydrophilic surfaces of objects. In some embodiments, Silquest® silane, Silquest® A-174 (NT) silane, or Silquest® A-174 silane is used throughout the method to coat objects with a Parylene compound. In one embodiment, the object may be contacted with the gaseous silane in a vacuum chamber.

In Step C, the silane may be vaporized by heating it to its evaporation point. In preferred embodiments, this step may be performed prior to contacting the object to be pretreated with the gaseous silane. In one embodiment, this step may be preformed by placing the silane into a crucible, inserting the crucible into a T′ thermocouple onto a hot place in the vacuum chamber containing the object to be coated. The amount of silane poured into the crucible may depend on the number and size of objects in the vacuum chamber. In various embodiments, the amount of silane vaporized may range from about 10 to about 100 ml, or in some cases more. In one embodiment, the hot plate may heat the silane to its evaporation point. In other embodiments, other methods to heat the silane to its evaporation point may be used, as will be well-known to those of ordinary skill in the art. In another embodiment, a mixture of silane with distilled water may be vaporized. In one embodiment, a 50/50 mix of silane and distilled water is heated until the silane is vaporized, which may be at about 80 degrees C. for about 2 hours.

While in some embodiments, the object may be pretreated with silane and then Parylene in the same vacuum chamber, in other embodiments, the two coatings may be applied in different chambers, and/or at different times. In a preferred embodiment, once the exposure of the object to the evaporated silane is complete, the chamber may be put under a vacuum, and the Parylene deposition may start as soon as a suitable vacuum is reached. It may be preferable to completely exhaust the silane vapor from the chamber before introducing the gaseous Parylene monomers. The period of time between the application of the silane pretreatment and the Parylene coating may be, in various embodiments, from about 0 minutes to about 120 minutes. The temperature of the evaporation point of silane is about 80 degrees C. While not limiting the mechanism of action of the silane, it is thought that the vaporized silane pretreats the object, increasing the ability of the surface to accept the Parylene monomer gas by causing the surface to have free radical sites to which the Parylene monomers will bond.

In Step D, the object to be coated may be contacted with gaseous silane. In preferred embodiments, this contacting may be done in the same deposition chamber that will later be used to contact the gaseous Parylene monomers to the object. In some embodiments, the object is contacted with the gaseous silane for a time of about 2 hours.

In Step E, the object to be coated may be contacted with gaseous Parylene monomers for sufficient time to deposit coat of Parylene. In preferred embodiments, this step may be performed in a deposition chamber, and particularly preferably in the same deposition chamber in which the object was contacted with silane. In other preferred embodiments, the deposition chamber and the objects to be coated may be at room temperature. In some embodiments, the deposition temperature may be about to about 30 degrees C., preferably about 20 to about 25 degrees C. In some embodiments, the deposition chamber may be refrigerated to speed up the deposition process.

Another embodiment provides a method to treat objects with silane. This method contains the following steps:

A. vaporizing silane by heating it to its evaporation point to form gaseous silane; and

B. contacting an object to be coated with gaseous silane.

In Step A, the silane may be vaporized by heating it to its evaporation point. In some embodiments, Silquest®, Silquest® A-174, Silquest® 111 or Silquest® 174(NT) is the silane throughout the method. In preferred embodiments, this step may be performed prior to contacting the object to be pretreated with the gaseous silane. In one embodiment, this step may be performed by placing thesilane into a crucible, inserting the crucible into a 2″ thermocouple onto a hot place in the vacuum chamber containing the object to be coated the amount of silane poured into the crucible may depend on the number and size of items in the vacuum chamber. In various embodiments, the amount of silane vaporized may range from about 10 to about 100 ml, or in some cases more. In one embodiment, the hot plate may heat the silane to its evaporation point. In other embodiments, other methods to heat the silane to its evaporation point may be used, as will be well known to those, of ordinary skill in the art. In another embodiment, a mixture of silane with distilled water may be vaporized. In one embodiment, a 50/50 mix of silane and distilled water may be heated until the silane is vaporized, which may be at about 80 degrees C. for about 2 hours.

In Step B, the object to be coated may be contacted with gaseous silane. In some embodiments, the object is contacted with the gaseous silane for a time of about 2 hours.

Methods for applying coatings that comprise a conformal coating compound and a thermally conductive material are also provided. In some embodiments, the methods involve heating a conformal coating compound to form gaseous monomers of the conformal coating compound; combining a thermally conductive material with the gaseous monomers, thereby forming a gaseous mixture, and contacting an object with the gaseous mixture, under conditions where a conformal coating comprising the conformal coating compound and the thermally conductive material is formed on at least a portion of a surface of the object, thereby applying a conformal coating to the object.

As used herein a “gaseous mixture” is a mixture that comprises at least one constituent in a vapor (gaseous) phase and at least one other constituent which may or may not be in a vapor phase. For example, a gaseous mixture may comprise a conformal coating compound in a vapor phase and a solid phase compound (e.g., a powder particle) suspended in the conformal coating compound vapors. Similarly, a gaseous mixture may comprise a conformal coating compound in a vapor phase and a liquid phase compound (e.g., a nebulized liquid) suspended in the conformal coating compound vapors. In addition, a gaseous mixture may comprise multiple vapor phase constituents (e.g., a plurality of different vapor phase conformal coating compounds). It is to be understood, that gaseous mixtures may include any number of combinations of constituents of the same and/or different phases. In some embodiments, the gaseous mixture comprises at least one vapor phase conformal coating compound (e.g., Parylene) and at least one thermally conductive material. In some embodiments, a thermally conductive material in a gaseous mixture is in a solid phase (e.g., a powder particles). In some embodiments, a thermally conductive material in a gaseous mixture is in a liquid phase. In still other embodiments, a thermally conductive material in a gaseous mixture is in a gaseous phase.

The coating methods disclosed herein may be used on products used in the commercial marine, recreational boating, military (aerospace and defense), industrial and medical industries, as well as others disclosed herein and known in the art. In some cases, the coating process may specifically be designed to “seal” a device. Thus, the coating methods may be useful to protects devices commonly used in marine and hazardous environments against operational malfunction caused by exposure to moisture, immersion in water, dust, effects of high wind and chemicals. The coating may enhance the survivability and sustainability of operational equipment and high value specialty products susceptible to corrosion and degradation.

In another aspect, the disclosure provides a method to apply a conformal coating comprising a Parylene compound and boron nitride to at least a portion of a surface of an object, which may have: (A.) vaporizing Parylene dimers by heating them to about 150 to about 200 degrees C. to form gaseous Parylene dieters; (B.) cleaving gaseous Parylene dimers to gaseous Parylene monomers by heating gaseous Parylene dimers to about 650 to about 700 degrees C.; (C.) injecting boron nitride into the gaseous Parylene monomers of Step B; and (D.) contacting the object to be coated with Parylene with the gaseous Parylene monomers and boron nitride of Step C for sufficient time to deposit coat of Parylene and boron nitride of a final thickness. While any Parylene may be used in this method, Parylene D, Parylene C, Parylene N and Parylene HT® may be preferred, and Parylene C may be particularly preferred. In some preferred embodiments, the boron nitride may be injected into the gaseous Parylene monomers as a powder, preferably between about 18 micron and about 25 micron. In other embodiments, Step D may take place at about degrees to about 30 degrees C. In some embodiments, the final thickness of the coat may be between about 100 Angstrom to about 3.0 millimeters. In some embodiments, the method may have an additional Step E in which the object to be coated may be contacted with a silane composition until the object is coated with silane.

In some embodiments, the method applies a uniform, thin layer of a conformal coating comprising a Parylene compound and boron nitride within a vacuum chamber at 25 degrees C. using standard chemical vapor deposition practices in thicknesses ranging from 0.01 to 3.0 millimeters, depending on the item coated. The item once coated is weatherproof and water resistant, and can withstand exposure to extreme weather conditions and exposure to most chemicals. Any solid surface can be coated, including plastics, metals, woods, paper and textiles. Sample applications include, but are not limited to: electronics equipment, such as cell phones, radios, circuit boards and speakers; equipment used in ocean and space exploration; hazardous waste transportation equipment; medical instruments; paper products; and textiles.

Thus, methods for coating objects with a composition of Parylene and boron nitrite may include the following several steps: A. vaporizing Parylene dimer form by heating to 150-200 degrees C. to form gaseous Parylene dimers; B. cleaving gaseous Parylene dimers to gaseous Parylene monomers by heating gaseous Parylene dimers to 650 to 700 degrees C.; C. injecting boron nitride into the gaseous Parylene monomers of Step B; and contacting the object to be coated with gaseous Parylene monomers and boron nitride for sufficient time to deposit coat of Parylene of a final thickness.

Steps A and B of the method to coat objects with Parylene and boron nitride may be performed by any manner that is currently in use for the vapor coating of objects with Parylene, as will be well known to those of ordinary skill in the art. Further, the steps may be performed in an order different than the one presented. In preferred embodiments, Parylene C is used. In other embodiments, other forms of Parylene may be used, including but not limited to, Parylene N, Parylene D and Parylene HT®. In some embodiments, the Parylene may be derived from Parylene N, or poly-para-xylylene, by the substitution of various chemical moieties. In preferred embodiments, the Parylene forms a completely linear, highly crystalline material. In the examples section, one embodiment of the method is set forth with a more detailed description on how the method may be performed.

In some embodiments, Step A, vaporizing Parylene dimer form by heating to 150-200 degrees C. to form gaseous Parylene dimers, may be performed in a furnace chamber. In some embodiments, Step B, cleaving gaseous Parylene dimers to gaseous Parylene monomers by heating gaseous Parylene dimers to 650 to 700 degrees C., may be performed in a furnace chamber. In some embodiments, Step C, injecting boron nitride into the gaseous Parylene monomers of Step B, may be performed after Step B. In some embodiments, the boron nitride may be injected into the gaseous Parylene monomer as a powder. One embodiment of this step is described in the Example. In some embodiments, the boron nitride powder may be at least about 500 grit. In some embodiments, the boron nitrate powder is between about 1.8 micron and about 2.5 micron.

In Step D, the object to be coated may be contacted with gaseous Parylene monomers and boron nitride for sufficient time to deposit a coat of Parylene and boron nitride on the object. In some embodiments, this step may be performed in a deposition chamber. In other embodiments, the deposition chamber and the objects to be coated may be at room temperature, from about degrees C. to about 30 degrees C., or most preferably from about 20 degrees C. to about 25 degrees C. In some embodiments, the length of time that the object may be contacted with the gaseous Parylene monomers and boron nitride may be varied to control the final thickness of the Parylene-boron nitride coat on the object. In various embodiments, the final thickness of the Parylene-boron nitride coating may be between about 100 Angstrom to about 3.0 millimeters. In some embodiments, Parylene is deposited from about 8 hours to about 18 hours to obtain a coat thickness of about 0.05 mm. In some embodiments, Parylene is deposited from about hours to about 18 hours to obtain a coat thickness of about 0.05 mm. In preferred embodiments, the final thickness of the Parylene coating may be between about 0.5 millimeters to about 3.0 millimeters. The choice of final thickness of Parylene coating depends to some degree on the object to be coated and the final use of the object. Thinner final coats may be desirable for objects that require some movement to be functional, such as power buttons. Thicker coatings may be desirable for objects that will be submerged in water.

In some embodiments, the method may have the additional step E of contacting the object to be coated with a silane composition until the object is pretreated with silane. In preferred embodiments, this step may be performed prior to Step D. In some embodiments, the silane composition may be in solution when the object is contacted with it. In other embodiments, the silane composition may be in a gas when the object is contacted with it. In some embodiments, the silane composition may be Silquest® A-174 silane (FIG. 1E). This step is particularly advantageous to aid the Parylene coating hydrophilic surfaces of objects.

### EXAMPLES

### Example 1

### Method and Apparatus Used to Coat an Object with Parylene

This embodiment uses Parylene C.

Coating Process

The apparatus consists of two sections: (1) a furnace/heating section; and (2) a vacuum section. The furnace section is made up of two furnaces which are connected by glass tubes referred to as retorts. The furnace and vacuum sections are connected by valves that allow gas flow between the furnace and vacuum sections.

The furnace portion of the equipment was fabricated by Mellen Furnace Co. (Concord, N.H. See Example 2. The vacuum portion was fabricated by Laco Technologies Inc. (Salt Lake City, Utah).

The process to coat items with Parylene is as follows:

(1) First Furnace Chamber. Parylene C in Dimer form (two molecule form) in an amount sufficient to coat the item is placed in the furnace chamber. The items are coated in a thickness ranging from 0.01 to 3.0 mms. The Parylene C is placed in a stainless steel “boat” (a standard container made out of metal or glass) that is inserted into the furnace through a vacuum secured opening of the tube (the boat is pushed with a rod into the furnace). The opening is sealed after inserting the Parylene C. The furnace is then brought to 150-200 degrees C. to create an environment in which the solid Parylene C becomes a gas. The gas is held in the first furnace chamber until two valves open. The first of two valves will not open until the cold traps in the vacuum section are filled with liquid nitrogen (LN2) and the traps are “cold”. The LN2 is purchased from a local supply house. The LN2 is placed into a one gallon container at the supplier. The LN2 is poured from the container into the “trap.” The second valve is variable and is opened when the gas is pulled from the first furnace by vacuum.

(2) Second Furnace Chamber. The Parylene C gas moves to the second furnace which is a temperature of 650 to 700 degrees C. The heat in this furnace causes the Parylene C gas to separate into individual molecules (monomers). The gas in monomer form is then pulled by vacuum into the deposition chamber.

(3) Vacuum Chamber. The vacuum portion of the machine consists of a deposition chamber with two vacuum pumps. The first vacuum pump is a “roughing” pump which pulls down the initial vacuum. The initial pressure is in the 1×10⁻³ Torr range. The second stage pump then pulls down to the final pressure in the 1×10⁴ Torr range. The vacuum pumps are protected by liquid nitrogen traps that protect the pumps from the solidification of the monomer gas by condensing the gas on the cold trap surface.

The items to be coated are set on shelves in the deposition chamber prior to starting the coating process. The devices to be coated are masked (with workmanlike methods) in those areas on and within the device that are not to be coated. The masking is done in areas where electrical or mechanical connectivity must remain. The material is coated onto the item at room temperature (75 degrees Fahrenheit).

Inside the vacuum chamber there is a crucible of Silquest® A-174 silane (Momentive Performance Materials Inc., Wilton, Conn.) that is poured into a ceramic crucible. The crucible is inserted into a 2 inch, thermocouple onto a hot plate in the vacuum chamber. The amount of Silquest® A-174 silane poured depends on the amount of items in the chamber, but is between 10-100 ml. The plate heats the Silquest® A-174 silane to an evaporation point such that it coats the entire area inside the chamber, included any objects within the chamber.

Once the Silquest vapor is evacuated from the deposition chamber, the monomer gas is pulled by the lower vacuum in the vacuum chamber. When the gas is pulled into the chamber it is deflected so that it sprays within the entire area of the chamber. The items are coated as the monomer gas cools. The gas cools from 600 degrees C. to 25 degrees C. and hardens on the device within the chamber. During that cooling process, the monomers deposit on the surface of the item to be coated creating a polymer three dimensional chain that is uniform and pin hole free. The deposition equipment controls the coating rate and ultimate thickness. The required thickness of a Parylene coating is, determined by time exposed to the monomer gas. The thickness can range from hundreds of angstroms to several millimeters.

### Example 2

### A Zoned Furnace that may be Used in the Apparatus to Apply a Coating of Parylene

This furnace assembly was fabricated by the Mellen Company, Inc., Concord N.H. One Mellen Model TV 12,

Single or two zoned—solid tubular furnace is capable of operation at temperatures up to 1200 degrees C. in air. The furnace utilizes the Mellen standard Series 12V heating elements (exposed Fe—Cr—Al windings within a special designed holder). The furnace has an energy efficient ceramic fiber insulation package alone with 2″ long vestibules. The thermocouples are placed at the center of each zone. A ten-foot long power cable for each zone is provided to facilitate connection to the power source. A furnace is designed for horizontal or vertical operation and has the following specifications:

TABLE 1

| MODEL: | TV 12-3x32-1/2Z | |
|---|---|---|
| Maximum Temperature | 1200 | degrees C. |
| Nominal Bore I.D. | 3 | inches |
| Heated Length of Furnace | 32 | inches |
| Furnace Outer Diameter Shell (a rox) | 10-12 | inches |
| Overall Furnace Length a rox.) | 36.25 | inches |
| No, of Furnace Zones | 1 or 2 | zones |
| Voltage (Nominal, 1 phase, 50/60 Hz.) | 208 | volts |
| Total Power | 6,400 | watts |

### Mellen Series PS205 Power Supply/Temperature Controller

One (1) Mellen Model PS205-208-(2)25-S, two zone, digital temperature controllers and solid state relay. The MELLEN Series PS205 consists of the following:

a.) Two (2) digital temperature controller calibrated for a Type “S” thermocouples featuring 126 segments & 31 programs.

b.) One (1) solid state relay.

c.) One (1) General Electric or equal circuit breaker, two pole, with appropriate-sized amperage rating.

d.) One (1) Mellen cabinet to house the above components.

e.) Two (2) Type “S” thermocouples including 10 it of compensated thermocouple extension wire, terminal boards, etc., per zone.

f.) All necessary wiring, terminal boards, interconnections, etc., to make a completely workable system.

### Over-temperature Protection for Power Supply/Temperature Controller

One (1) over-temperature (O.T.) alarm utilizing an independent digitally indicating, digital set-point “hi-limit alarm” controller. The O.T. Alarm package is furnished, with an appropriate thermocouple, TIC extension wire, and sufficient mechanical power contactor(s) to interrupt power to the furnace in the event of an over temperature condition at the location of the over-temperature sensor. The O.T. alarm option is mounted in the main temperature controller enclosure.

Retort Model: RTA -2.5 x32-OBE

One (1) Mellen Model RTA-2.5-32-OBE, round, Hi-Purity Alumina (actual system has a Quartz retort) retort to be used with the furnace described above. The retort working diameter is approximately 2.5 inches 1.D. by 32 inches. The retort has an O.D. of approximately 2.75″ inches and is 48″ inches long & contains the necessary stainless steel flange/seal assemblies, & heat shields to permit gas tight operation. Feedthroughs are provided in the cover plates of the retort for gas in/out and temperature measurement. The retort is capable of operating with different types of atmospheres.

### Example 3

### Method and Apparatus Used to Coat an Object with Parylene and Boron Nitride

This embodiment uses Parylene C.

Coating Process

The apparatus will consist of two sections: (1) a furnace/heating section; and (2) a vacuum section. The furnace section will be made up of two furnaces which are connected by glass tubes referred to as retorts. The furnace and vacuum sections will be connected by valves that allow gas flow between the furnace and vacuum sections.

The furnace portion of the equipment was fabricated by Mellen Furnace Co. (Concord, N.H. The vacuum portion was fabricated by Laco Technologies Inc. (Salt Lake City, Utah).

The process to coat items with Parylene and boron nitride will be is as follows:

(1) First Furnace Chamber. Parylene C in Dimer form (two molecule form) in an amount sufficient to coat the item is placed in the furnace chamber. The items are coated in a thickness ranging from 0.01 to 3.0 mms. The Parylene C is placed in a stainless steel “boat” (a standard container made out of metal or glass) that is inserted into the furnace through a vacuum secured opening of the tube (the boat is pushed with a rod into the furnace). The opening is sealed after inserting the Parylene C. The furnace is then brought to 150-200 degrees C. to create an environment in which the solid Parylene C becomes a gas. The gas is held in the first furnace chamber until two valves open. The first of two valves will not open until the cold traps in the vacuum section are filled with liquid nitrogen (LN2) and the traps are “cold”. The LN2 is purchased from a local supply house. The LN2 is placed into a one gallon container at the supplier. The LN2 is poured from the container into the “trap.” The second valve is variable and is opened when the gas is pulled from the first furnace by vacuum.

(2) Second Furnace Chamber. The Parylene C gas will move to the second furnace which is a temperature of 650 to 700 degrees C. The heat in this furnace will cause the Parylene C gas to separate into individual molecules (monomers). The gas in monomer form is then pulled by vacuum into the deposition chamber.

Boron nitride in powder form is placed in a KF tube that is connected to a KF connection tube that has a “T” KF port. This K1716 tube is partially filled with a “charge” of boron nitride powder (minimum of 500 grit). The KF tube is capped. After the coating process is initiated, the boron is injected into the coating “stream.” The boron flows as a powder and will become entrapped with the deposition of the coating process.

The K1716 tube is attached to the retort perpendicular to the flow of the monomer gas just before it enters the deposition chamber. There is a valve that is opened which allows the boron nitride to flow into the gas. The gas will bind with the monomer and is deposited on the items to be coated. This process is similar to powder coating. The process may be repeated to increase the amount of boron nitride inserted into the coating on the items. While not limiting the characteristics of the boron nitride/Parylene coating, it is thought that boron nitride improves the hardness of the coat and supplies a method to better allow the heat to escape the coated object, such as an electronic device. The boron nitride is inserted into the Parylene as a dust.

(3) Vacuum Chamber. The vacuum portion of the machine will consist of a deposition chamber with two vacuum pumps. The first vacuum pump is a “roughing” pump which pulls down the initial vacuum. The initial vacuum is in the 1×10-3 Torr range. The second stage pump then will pull down to the final vacuum in the 1×10-4 Torr range. The vacuum pumps are protected by Liquid Nitrogen traps that protect the pumps from the solidification of the monomer gas by condensing the gas on the cold trap surface.

The items to be coated are set on shelves in the deposition chamber prior to starting the coating process. The devices to be coated are masked (with workmanlike methods) in those areas on and within the device that are not to be coated. The masking is done in areas where electrical or mechanical connectivity must remain. The material is coated onto the item at room temperature (75 degrees Fahrenheit).

Inside the vacuum chamber there is a crucible of Silquest® A-174 silane that is poured into a ceramic crucible. The crucible is inserted into a 2 inch thermocouple onto a hot plate in the vacuum chamber. The amount of Silquest® A-174 silane poured depends on the amount of items in the chamber, e.g., between 10-100 ml. The plate will heat the Silquest® A-174 silane to an evaporation point such that it coats the entire area inside the chamber, included any objects within the chamber.

The monomer gas is pulled by the lower vacuum in the vacuum chamber. When the gas is pulled into the chamber it is deflected so that it sprays within the entire area of the chamber. The items are coated as the monomer gas cools. The gas will cool from 600 degrees C. to 25 degrees C. and will harden on the device within the chamber. During that cooling process, the monomers deposit on the surface of the item to be coated will create a polymer three dimensional chain that is uniform and pin hole free. The deposition equipment will control the coating rate and ultimate thickness. The required thickness of a Parylene coating is determined by time exposed to the monomer gas. The thickness can range from hundreds of angstroms to several millimeters.

While several aspects and embodiments of the invention have been described, it should be apparent, however, that various modifications, alterations and adaptations to those embodiments may occur to persons skilled in the art with the attainment of some or all of the advantages of the present invention. For example, in some embodiments of the present invention disclosed herein, a single component may be replaced by multiple components, and multiple components may be replaced by a single component, to perform a given function or functions. Except where such substitution would not be operative to practice embodiments of the present invention, such substitution is within the scope of the present invention. The disclosed embodiments are therefore intended to include all such modifications, alterations and adaptations without departing from the scope and spirit of the present invention as defined by the appended claims. Preferred features of each aspect and embodiment of the invention are as for each of the other aspects and embodiments mutatis mutandis.

It is to be further understood that the figures and descriptions of the present disclosure have been simplified to illustrate elements that are relevant for a clear understanding of the present disclosure, while eliminating, for purposes of clarity, other elements, e.g., components of a conventional conformal coating method or apparatus. For example, certain conformal coating systems may include additional components, e.g., deposition chambers, valves, vacuum pumps, that are not described herein. Those of ordinary skill in the art will recognize, however, that these and other elements may be desirable in a typical conformal coating system. However, because such elements are well known in the art and because they do not facilitate a better understanding of the present disclosure, a discussion of such elements is not provided herein.

Also, in the claims appended hereto, any element expressed as a means for performing a specified function is to encompass any way of performing that function including, for example, a combination of elements that perform that function. Furthermore an invention, as defined by means-plus-function claims, resides in the fact that the functionalities provided by the various recited means are combined and brought together in a manner as defined by the appended claims. Therefore, any means that can provide such functionalities may be considered equivalents to the means shown herein.

For the purposes of this specification, unless otherwise indicated, all numbers expressing quantities of ingredients, time, temperature, thickness of coats, and other properties or parameters used in the specification are to be understood as being modified in all instances by the term “about.” Accordingly, unless otherwise indicated, it should be understood that the numerical parameters set forth in the following specification and attached claims are approximations. At the very least, and not as an attempt to limit the application of the doctrine of equivalents to the scope of the claims, numerical parameters should be read in light of the number of reported significant digits and the application of ordinary rounding techniques.

Additionally, while the numerical ranges and parameters setting forth the broad scope of the invention are approximations as discussed above, the numerical values set forth in the Examples section are reported as precisely as possible. It should be understood, however, that such numerical values inherently contains certain errors resulting from the measurement equipment and/or measurement technique.

Any patent, publication, or other disclosure material, in whole or in part, that is said to be incorporated by reference herein is incorporated herein only to the extent that the incorporated material does not conflict with the existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements or other disclosure material set forth herein will only be incorporated to the extent that no conflict arises between the incorporated material and the existing disclosure material.

1. A coating composition, comprising a conformal coating compound and a thermally conductive material.

2. The coating composition of claim 1, wherein the conformal coating compound comprises a Parylene compound optionally including at least one of: Parylene D, Parylene C, Parylene N and Parylene HT®.

3. (canceled)

4. (canceled)

5. The coating composition of claim 1, wherein the thermally conductive material comprises a ceramic material.

6. The coating composition of claim 5, wherein the ceramic material comprises at least one of aluminum nitride, aluminum oxide, and boron nitride.

7. The coating composition of claim 1, wherein the thermally conductive material has volume resistivity of greater than 10¹⁰ ohms*cm.

8. The coating composition of claim 1, wherein the mass of the thermally conductive material is up to about 3% of the total mass of the conformal coating compound and the thermally conductive material.

9. (canceled)

10. The coating composition of claim 1, having a thermal conductivity that is 5-10% greater than the thermal conductivity of the conformal coating compound alone.

11-19. (canceled)

20. A waterproofed object, comprising:
an object including at least one surface; and
a conformal coating on at least a portion of the at least one surface, the conformal coating including a conformal coating compound and. a thermally conductive material.

21. The waterproofed object of claim 20, wherein the object is an electronic device, optionally selected from a communication device, a speaker, a cell phone, an audio player, a camera, a video player, a remote control device, a global positioning system, a computer component, a radar display, a depth finder, a fish finder, an emergency position-indicating radio beacon (EPIRB), an emergency locator transmitter (ELT), and a personal locator beacon (PLB).

22. The waterproofed object of claim 20, wherein the object is selected from the group consisting of a paper product; a textile product; an artwork, a circuit board; an ocean exploration device, a space exploration device, a hazardous waste transportation device; an automotive device, a electromechanical device; a military systems component; ammunition; a gun; a weapon; a medical instrument; and a biomedical device, wherein the biomedical device is optionally selected from the group consisting of a hearing aid, a cochlear ear implant, and prosthesis.

23. (canceled)

24. The waterproofed object of claim 20, wherein the at least one surface comprises an external surface of the object.

25. (canceled)

26. A method of applying a conformal coating to an object, comprising:
heating a conformal coating compound to form gaseous monomers of the conformal coating compound,
combining a thermally conductive material with gaseous monomers, thereby forming a gaseous mixture, and
contacting an object with the gaseous mixture, under conditions where a conformal coating comprising the conformal coating compound and the thermally conductive material is formed on at least a portion of a surface of the object, thereby applying a conformal coating to the object.

27. The method of claim 26, wherein the conformal coating compound comprises a Parylene compound optionally including at least one of Parylene D, Parylene C, Parylene N and Parylene HT®.

28. The method of claim 27, wherein the thermally conductive material comprises a ceramic material.

29. (canceled)

30. The method of claim 26, wherein the thermally conductive material is in a solid particle form.

31. The method of claim 30, wherein the solid particles have dimension of from about 1.8 microns to about 2.5 microns.

32. The method of claim 26, wherein heating the conformal coating compound comprises:
heating the conformal coating compound to a temperature of about 125° C. to about 200° C. to form a gaseous conformal coating compound; and
heating the gaseous conformal coating compound to a temperature of about 650° C. to about 700° C. to cleave the gaseous conformal coating compound and to form the gaseous monomers.

33-38. (canceled)

39. The method of claim 32, wherein the object is at a temperature of about 5° C. to about 30° C. meting the object with gaseous mixture.

40-56. (canceled)

57. The waterproofed object of claim 20, wherein the conformal coating has a thickness of about 100 Å to about 3.0 mm.

58. The waterproofed object of claim 20, wherein the conformal coating has a thickness of about 0.0025 mm to about 0.0500 mm.
